(19) United States
(12) Patent Application Publication
(10) Pub. No.: US 2018/0087186 A1
(43) Pub. Date: Mar. 29, 2018

(54) METHOD OF PRODUCING CARBIDE RAW MATERIAL

(71) Applicant: NATIONAL CHUNG SHAN INSTITUTE OF SCIENCE AND TECHNOLOGY, TAOYUAN CITY (TW)

(72) Inventors: CHENG-JUNG KO, TAOYUAN CITY (TW); DAI-LIANG MA, TAOYUAN CITY (TW); BO-CHENG LIN, TAOYUAN CITY (TW); HSUEH-I CHEN, TAOYUAN CITY (TW); BANG-YING YU, TAOYUAN CITY (TW); SHU-YU YEH, TAOYUAN CITY (TW)

(21) Appl. No.: 15/352,048

(22) Filed: Nov. 15, 2016

(30) Foreign Application Priority Data
Sep. 23, 2016 (TW) 105130692

(51) Int. Cl. C30B 29/36; C30B 23/02; C01B 31/36

(52) U.S. Cl. CPC C30B 29/36; C01B 31/36; C30B 23/02

(57) ABSTRACT

A method of producing a carbide raw material includes the steps of (A) providing a porous carbon material and a high-purity silicon raw material or a metal raw material and applying the porous carbon material and the high-purity silicon raw material or a metal raw material alternately to form a layer structure; (B) putting the layer structure in a synthesis furnace to undergo a gas evacuation process; and (C) producing a carbide raw material with a synthesis reaction which the layer structure undergoes in an inert gas atmosphere, wherein the carbide raw material is a carbide powder of a particle diameter of less than 300 μm, thereby preventing secondary raw material contamination otherwise arising from comminution, oxidation and acid rinsing.

### CROSS-REFERENCE TO RELATED APPLICATION

This non-provisional application claims priority under 35 U.S.C. §119(a) on Patent Application No(s).105130692 filed in Taiwan, R.O.C. on Sep. 23, 2016, the entire contents of which are hereby incorporated by reference.

### FIELD OF THE INVENTION

The present invention relates to methods of producing a raw material and, more particularly, to a method of producing a carbide powder raw material.

### BACKGROUND OF THE INVENTION

Due to rapid development of modern technology and quality of life, various 3C high-tech electronic products are becoming lighter, thinner, smaller and more versatile. To this end, carbides, metal carbides, and the like are developed and applied to the semiconductor materials for manufacturing various electronic devices. In this regard, silicon carbide (SiC) crystals high physical strength, high resistance to corrosion, satisfactory electronic features, high hardness of radiation, high breakdown field strength, wide bandgap, high saturated electron drift velocity, and satisfactory high-temperature operability.

The commonest conventional method of producing a silicon carbide raw material is the Acheson process which entails mixing quartz grain (SiO₂) and carbon (C) evenly in a muffle furnace, and heating the mixture to at least 2000° C. to form coarse carbide powder. Regarding the Acheson process, excess reagents are present in the samples at the end of the reaction. In general, the samples are heated to 600˜1200° C. or above to remove excess carbon therefrom by oxidation. Then, excess metal oxides or silicon dioxide are removed by an acid rinsing process. Finally, the samples are ground into powder to reduce their sizes so as to obtain silicon carbide powder of different sizes by a sorting process. The silicon carbide raw material thus produced contains plenty impurities and thus must be refined before being put into use. However, due to process limits, the refined raw material is not of sufficient purity to be applicable to any silicon carbide crystal-growing process.

A conventional method of producing a metal carbide requires that a metal oxide be subjected to a plasma flame of up to 10,000° C. so that oxygen gas is released from the metal oxide, and then the oxygen gas reacts with carbon present in a solvent, such as an alcohol, thereby producing various metal carbides. However, due to the high melting point and boiling point of carbon, the conventional method is disadvantaged by poor process control. As a result, metal carbides cannot be steadily produced with the conventional method by mass production.

Disadvantages of the Acheson process are further described below. The forms of its carbon source and metal oxide or silicon raw material are restricted to powder and particles. However, in the course of its preservation and delivery, fine powder is predisposed to dust storms. A carbide raw material synthesized by the Acheson process ends up in the form of a briquette because of a sintering process, and has to undergo subsequent processes, such as comminution, oxidation, and acid rinsing before producing a low-impurity carbide powder raw material.

In view of this, it is important to provide a method of producing a carbide raw material for manufacturing carbide powder of a particle diameter of less than 300 μm, so as to promote the production efficiency and protect the environment.

### SUMMARY OF THE INVENTION

In view of the aforesaid drawbacks of the prior art, it is an objective of the present invention to provide a method of producing a carbide raw material, integrating a porous carbon material, a high-purity silicon raw material, a metal raw material, a synthesis furnace, and a synthesis reaction, so as to obtain the intended carbide powder raw material.

In order to achieve the above and other objectives, the present invention provides a method of producing a carbide raw material, comprising the steps of: (A) providing a porous carbon material and a high-purity silicon raw material or a metal raw material and applying the porous carbon material and the high-purity silicon raw material or a metal raw material alternately to form a layer structure; (B) putting the layer structure in a synthesis furnace to undergo a gas evacuation process; and (C) producing a carbide raw material with a synthesis reaction which the layer structure undergoes in an inert gas atmosphere, wherein the carbide raw material is a carbide powder of a particle diameter of less than 300 μm.

In step (A), the metal raw material is one selected from the group consisting of titanium, tungsten, hafnium, zirconium, vanadium, chromium, tantalum, boron, niobium, aluminum, manganese, nickel, iron, cobalt, molybdenum, and an oxide of the selected one. The porous carbon material and the high-purity silicon raw material are of a purity of at least 99.99%, and preferably 99.99999%. If the silicon raw material purity is too low, the silicon carbide raw material thus synthesized will contain excessive impurities and thus will be inapplicable to a growing process of the monocrystalline silicon carbide. The porous carbon material is of a porosity of 20%˜85%; if the porosity of the synthesized silicon carbide structure is too low, the porous carbon material will not be decomposed in a manner to take on a powder-shape but will need to undergo a comminution process in order to form a silicon carbide powder. The porous carbon material is one selected from the group consisting of a graphite felt, a graphite insulator, a carbon foam, a carbon nanotube, a carbon fiber, and an activated carbon. The aforesaid material is a non-powder raw material (but the present invention is not limited thereto). The high-purity silicon raw material silicon is of a thickness of 10 μm˜10000 μm and is one of a silicon wafer, a silicon ingot, a silicon chip, and a silicon briquette (but the present invention is not limited thereto); if its thickness is less than 10 μm, the synthesized silicon carbide raw material will have overly high carbon content; if its thickness is larger than 10000 μm, its silicon content will be overly high; both scenarios render the synthesized silicon carbide raw material inapplicable to a growing process of silicon carbide crystals. Likewise, the metal raw material is one of a metal ingot, a metal briquet, a non-powder metal oxide or metal raw material (but the present invention is not limited thereto).

In step (B), the gas evacuation process removes nitrogen gas and oxygen gas from the synthesis furnace so that the pressure therein is reduced to less than 1×10⁻⁶ torr, and the synthesis furnace is heated to 900˜1250° C. (but the present invention is not limited thereto) to passivate the carbon material. In step (C), the synthesis reaction occurs at 1800° C.˜2200° C. (but the present invention is not limited thereto) and 5˜600 torr (but the present invention is not limited thereto).

According to the present invention, step (A) further comprises filling an element raw material at a bottom (or any other part) of the layer structure. Likewise, the element raw material is a non-powder raw material (but the present invention is not limited thereto). If the element raw material is one of aluminum, boron, vanadium, scandium, iron, cobalt, nickel, and titanium, the carbide produced as a result of steps (A), (B), (C) will serve as the raw material for undergoing a conventional crystal-growing process to produce p-type crystals. If the element raw material is one of nitrogen, phosphorus, arsenic, and stibium, the carbide produced as a result of steps (A), (B), (C) will serve as the raw material for undergoing a conventional crystal-growing process and the element raw material reaction to produce n-type crystals.

The above summary, the description below, and the accompanying drawings are intended to further explain the measures and means used by the present invention to achieve predetermined objects and the advantages of the present invention. The other objects and advantages of the present invention are described hereunder with reference to the description and the accompanying drawings.

### BRIEF DESCRIPTION OF THE DRAWINGS

FIG. 1 is a schematic view of a synthesis apparatus for synthesizing a carbide raw material according to the present invention;

FIG. 2 is a flow chart of a method of producing a carbide raw material according to the present invention;

FIG. 3 is a schematic view of a layer structure of the present invention;

FIG. 4 shows XRD pattern of the carbide raw material according to embodiment 1 of the present invention;

FIG. 5 is an SEM picture of the carbide raw material according to embodiment 1 of the present invention;

FIG. 6 shows XRD pattern of the carbide raw material according to embodiment 2 of the present invention;

FIG. 7 is an SEM picture of the carbide raw material according to embodiment 2 of the present invention; and

FIG. 8 shows XRD pattern of the carbide raw material according to embodiment 3 of the present invention.

### DETAILED DESCRIPTION OF THE PREFERRED EMBODIMENTS

The implementation of the present invention is hereunder illustrated with preferred embodiments. Persons skilled in the art can easily understand the advantages and benefits of the present invention by referring to the disclosure presented below.

The production of a carbide is hereunder exemplified by silicon carbide, which is essentially a mixture of quartz grain (SiO₂) and carbon (C). The silicon carbide is formed by electric-arc heating (SiO₂+3C→SiC+2CO) and then undergoes a high-temperature reaction. By controlling the reaction temperature, different results can be obtained. If the reaction temperature is lower than 1800° C., β-phase silicon carbide raw material is produced. If the reaction temperature falls within the range of 1800° C.˜2000° C., the silicon carbide raw material exists in both β phase and α phase. If the reaction temperature is higher than 2000° C., the silicon carbide raw material exists in a phase. If the reaction temperature is higher than 2300° C., the silicon carbide raw material undergoes carbonization. However, in the aforesaid step, the reaction between carbon powder and silicon powder does not produce silicon carbide raw material solely; instead, part of the carbon powder and part of the silicon powder do not join the reaction. To be removed, the unreacted carbon powder must undergo an oxidation process at 600° C˜1200° C.; however, the oxidation process turns the unreacted silicon raw material into silicon dioxide which has to be removed by undergoing a conventional RCA cleaning process well known in the semiconductor manufacturing industry. However, with the reaction taking place at high temperature, powder-like silicon carbide raw material gets sintered and takes on a briquet-shape; as a result, the briquet-shaped silicon carbide raw material must undergo a comminution process in order to undergo the other semiconductor process.

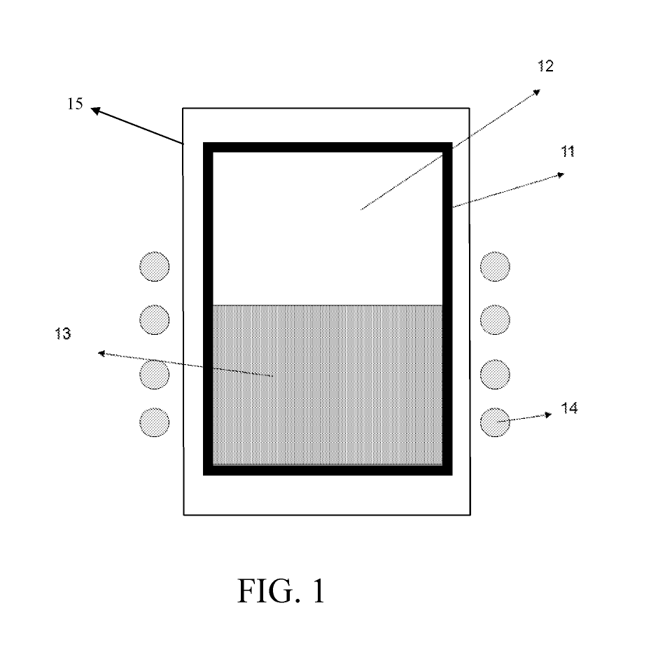

According to the present invention, the method of producing a carbide raw material dispenses with the need to use powder as a synthesis raw material and thus avoids the danger which might otherwise happen in the course of the powder delivery. Furthermore, according to the present invention, the method of producing a carbide raw material is advantageously characterized in that synthesized products bring silicon carbide powder without undergoing the comminution, oxidation and rinsing processes, so as to reduce the pollution caused by the later processes and prevent the dust storms otherwise caused by the comminution process. Referring to FIG. 1, there is shown a schematic view of a synthesis apparatus for use with a carbide raw material according to the present invention. As shown in the diagram, the synthesis apparatus comprises a graphite crucible 11. The graphite crucible 11 comprises a cover and a crucible body. The crucible body has therein a growth chamber 12, a material source 13 and a heat source 14. The crucible cover is disposed above the growth chamber 12. The material source 13 is disposed below the growth chamber 12. The graphite crucible 11 is disposed in a synthesis furnace 15 and at the relative heat end of a heat field.

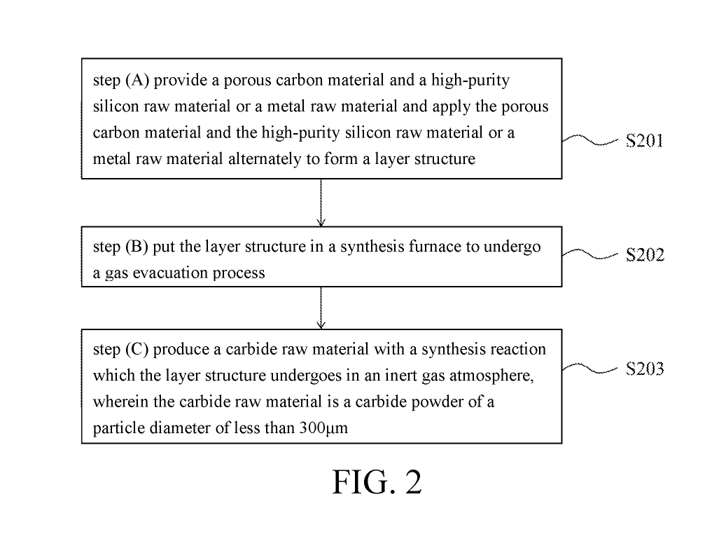

Referring to FIG. 2, there is shown a flow chart of a method of producing a carbide raw material according to the present invention. As shown in the diagram, a method of producing a carbide raw material of the present invention comprises the steps of: (A) providing a porous carbon material and a high-purity silicon raw material or a metal raw material and applying the porous carbon material and the high-purity silicon raw material or a metal raw material alternately to form a layer structure S201, wherein, in this embodiment, the metal raw material is one selected from the group consisting of titanium, tungsten, hafnium, zirconium, vanadium, chromium, tantalum, boron, niobium, aluminum, manganese, nickel, iron, cobalt, molybdenum, and an oxide of the selected one, whereas the porous carbon material is one of a graphite felt, a graphite insulator, a carbon foam, a carbon nanotube, a carbon fiber, and an activated carbon, and the high-purity silicon raw material silicon is of a thickness of 10 μm˜10000 μm and is a silicon wafer, silicon ingot, silicon chip or silicon briquet; (B) putting the layer structure in a crucible and then in a synthesis furnace to undergo a gas evacuation process S202, wherein the synthesis furnace comprises a graphite crucible, and the layer structure is disposed within a material source region in the graphite crucible; and (C) producing a carbide raw material with a synthesis reaction which the layer structure undergoes in an inert gas atmosphere, wherein the carbide raw material is a carbide powder of a particle diameter of less than 300 μm S203.

### Embodiment 1

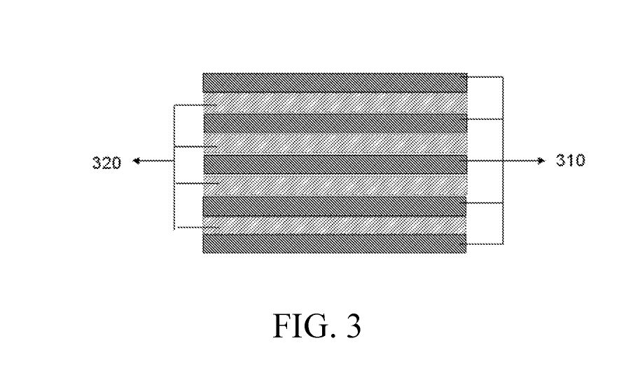

FIG. 3 is a schematic view of a layer structure of the present invention. In this embodiment, a high-purity silicon raw material—silicon chip (of a thickness of 100˜5000 μm, preferably 1500 μm) and a porous carbon material—graphite felt (of a thickness of 1000˜0000 μm, preferably 5000 μm) are provided in a molar ratio of 1.0˜1.2:1, wherein both have a purity of at least 99.99%, and then the silicon wafer (320) and the graphite felt (310) are applied in a sandwich-like manner to produce the layer structure as shown in FIG. 3. The layer structure is put in a graphite crucible, and then the graphite crucible is put in a synthesis furnace before the synthesis furnace undergoes a gas evacuation process to remove nitrogen gas and oxygen gas from the synthesis furnace and the material source region. At this point in time, the synthesis furnace is heated to 900˜1250° C. to admit a high-purity inert gas (such as argon gas, helium gas, or a mixture of argon gas and hydrogen gas) of a purity of at least 99.999%. The synthesis furnace stays at 900˜1250° C. for one hour to passivate graphite. Afterward, the synthesis furnace is heated to 1800° C.˜2200° C. so as for the synthesis process to take place therein at 5˜600 torr for 4˜12 hours before the synthesis furnace is cooled down to room temperature. In this embodiment, the reaction occurs between silicon vapor and the graphite felt whose fibers are thin; since the graphite felt undergoes the reaction to produce silicon carbide and thus becomes brittle, the original structure of the graphite felt disintegrates, thereby producing a high-purity silicon carbide powder of a diameter of less than 300 μm. The silicon wafer (320) may be replaced by one selected from titanium, tungsten, hafnium, zirconium, vanadium, chromium, tantalum, boron, niobium, aluminum, manganese, nickel, iron, cobalt, molybdenum, and an oxide of the selected one to produce different metal carbides.

In this embodiment, a silicon chip or a silicon wafer and a graphite felt undergo a reaction at high temperature to produce a silicon carbide raw material, thereby dispensing with the hassles of mixing a carbon powder and a silicon powder. In this embodiment, the graphite felt is rather loose and thus decomposes during the reaction in which a silicon carbide powder is formed at high temperature, thereby dispensing with a comminution process; furthermore, the conversion rate of the silicon carbide raw material synthesis is increased by controlling the pressure and temperature at which the reaction occurs and the time the reaction takes.

### Embodiment 2

Embodiment 2 uses the same synthesis steps and material application technique as embodiment 1. Referring to FIG. 1, in embodiment 2, different elements are applied to the bottom of the raw material, whereas doping is carried out in the course of the carbide raw material synthesis, using dopants, such as aluminum, boron, vanadium, scandium, iron, cobalt, nickel, and titanium, and a growing process of silicon carbide crystals is performed on a carbide raw material (powdered silicon carbide) to produce p-type crystals. In the course of synthesis, n-type crystals will be produced, if a dopant, such as nitrogen, phosphorus, arsenic, and stibium, is used, and the growing process of silicon carbide crystals is performed on the carbide raw material (powdered silicon carbide). In this embodiment, aluminum is used as a dopant in the raw material synthesis to undergo the synthesis steps of embodiment 1 to produce the silicon carbide raw material doped with different elements, and then oxidation and acid rinsing processes are carried out to remove unreacted raw materials (carbon, silicon, aluminum) to produce the silicon carbide raw material doped with different elements, thereby turning an n-type silicon carbide raw material into a p-type silicon carbide raw material.

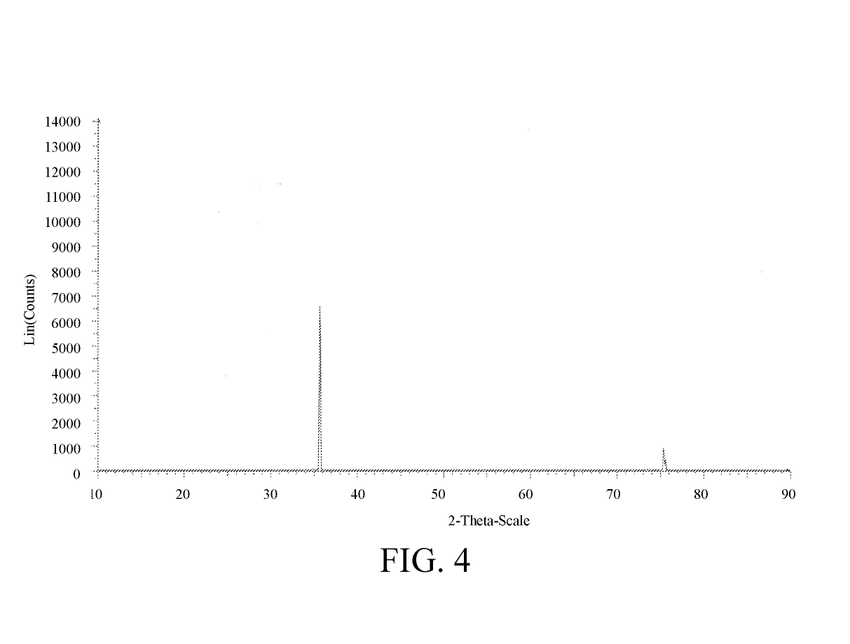

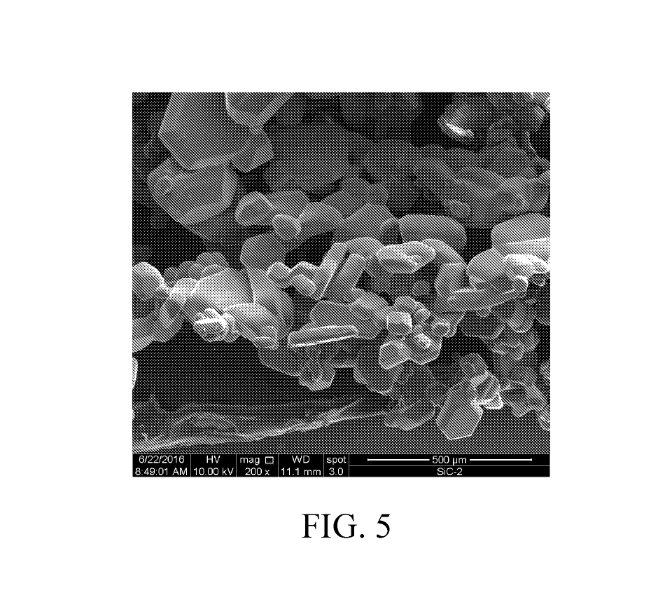

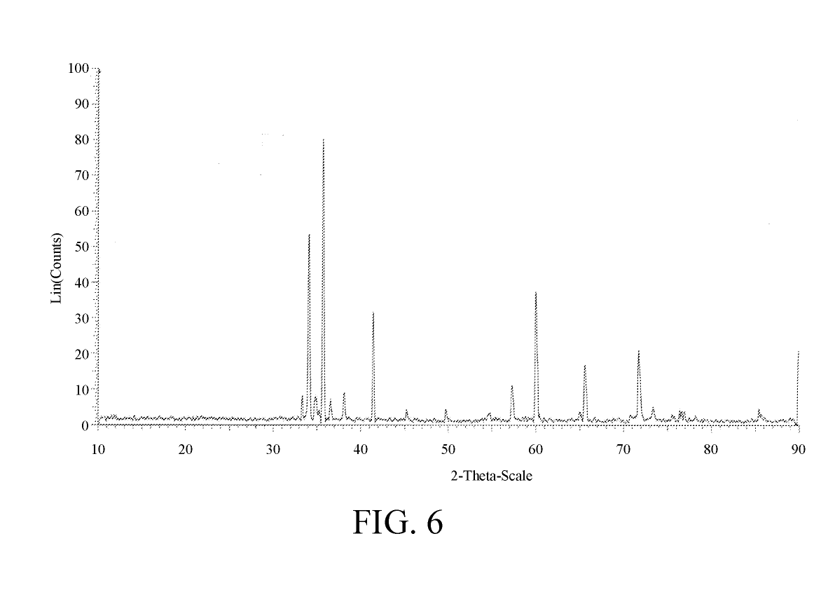

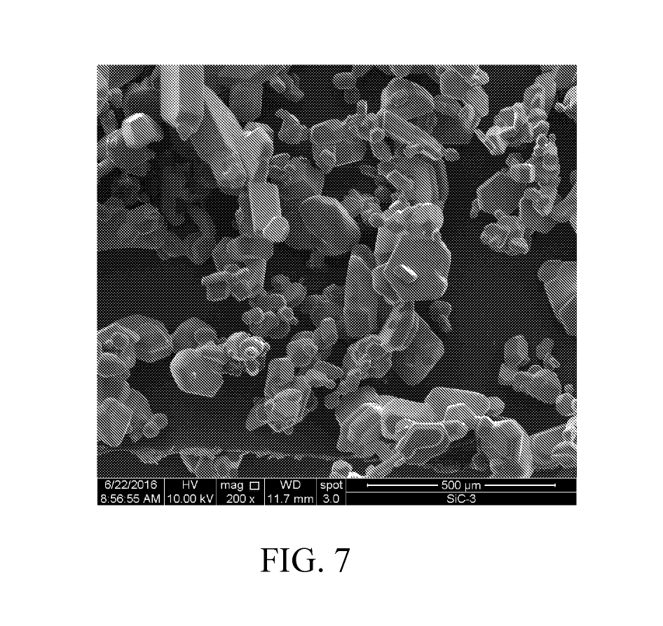

FIG. 4 shows XRD pattern of the carbide raw material according to embodiment 1 of the present invention. FIG. 5 is an SEM picture of the carbide raw material according to embodiment 1 of the present invention. FIG. 6 shows XRD pattern of the carbide raw material according to embodiment 2 of the present invention. FIG. 7 is an SEM picture of the carbide raw material according to embodiment 2 of the present invention. As shown in the diagrams, after a carbide raw material has been synthesized with the method of producing a carbide raw material according to the present invention, the silicon carbide powder produced in embodiment 1 undergoes analysis by XRD and GDMS to yield the findings as follows: with the production method of embodiment 1, the silicon carbide powder is directly produced, and the untreated powder is directly analyzed by XRD to show that it contains mainly a-phase silicon carbide structure (shown in FIG. 4) and by GDMS to show that it has a purity of at least 99.9995% (shown in Table 1). Referring to FIG. 5, the silicon carbide raw material powder is of a diameter of less than 300 μm. In embodiment 2, the produced silicon carbide powder is analyzed by XRD to show that, due to the doping of aluminum, a-phase silicon carbide raw material (shown in FIG. 6) is produced, though it is relatively multi-faceted, and by GDMS to show that, due to the doping of aluminum, the overall purity decreases to 99.983% (shown in Table 2). However, both Table 1 and Table 2 show that embodiment 1 differs from embodiment 2 in terms of the synthesized raw material. FIG. 7 shows that the silicon carbide raw material powder doped with aluminum is of a diameter of less than 300 μm.

TABLE 1
GDMS analysis (ppm) of silicon
carbide powder obtained in embodiment 1

| iron | nickel | copper | aluminum | sodium | boron | magnesium | vanadium |
|---|---|---|---|---|---|---|---|
| 0.62 | 0.13 | <0.05 | 1.9 | <0.01 | <0.01 | <0.05 | 0.67 |

TABLE 2
GDMS analysis (ppm) of
silicon carbide powder obtained in embodiment 2

| iron | nickel | copper | aluminum | sodium | boron | magnesium | vanadium |
|---|---|---|---|---|---|---|---|
| 0.28 | <0.05 | <0.05 | 170 | <0.01 | <0.01 | <0.05 | <0.01 |

### Embodiment 3

Embodiment 3 uses substantially the same synthesis steps and material application technique as embodiment 1, but uses a titanium (Ti) plate of a thickness of 1500 μm rather than a silicon raw material for synthetic purposes. The devices for use in embodiment 3 are shown in FIG. 1. In embodiment 3, a metal carbide raw material is synthesized according to a molar ratio 1.0˜1.2:1 of titanium plate:porous carbon material graphite felt. Embodiment 3 uses a titanium plate instead of the silicon wafer (320) and applies the titanium plate and graphite felt (310) in a sandwich-like manner to produce the layer structure shown in FIG. 3. After the layer structure has been put in a graphite crucible, the graphite crucible is put in a synthesis furnace such that the synthesis furnace undergoes a gas evacuation process to remove nitrogen gas and oxygen gas from the synthesis furnace and the material source region. At this point in time, the synthesis furnace is heated to 900˜1250° C. to admit a high-purity inert gas (such as argon gas, helium gas, or a mixture of argon gas and hydrogen gas) of a purity of at least 99.999%. The synthesis furnace stays at 900˜1250° C. for one hour to passivate graphite. Afterward, the synthesis furnace is heated to 1800° C.˜2200° C. so as for the synthesis process to take place therein at 5˜600 torr for 4˜12 hours before the synthesis furnace is cooled down to room temperature. In embodiment 3, the reaction occurs between titanium vapor and the graphite felt whose fibers are thin; the titanium plate (320) may be replaced by one selected from tungsten, hafnium, zirconium, vanadium, chromium, tantalum, boron, niobium, aluminum, manganese, nickel, iron, cobalt, molybdenum, and an oxide of the selected one to produce different metal carbides.

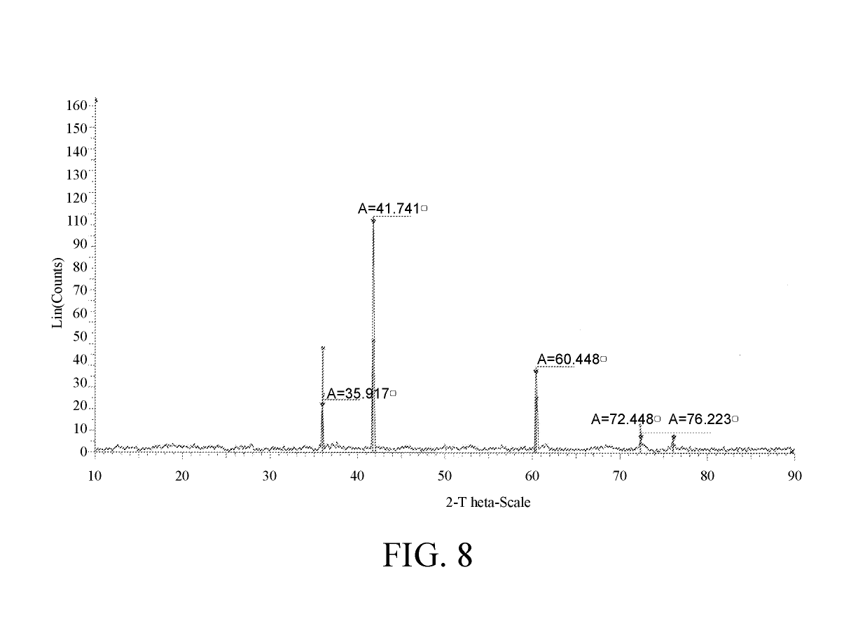

FIG. 8 shows XRD pattern of the carbide raw material according to embodiment 3 of the present invention. In embodiment 3, a titanium carbide (TiC) raw material is produced from the carbide raw material, as shown by the analysis performed with XRD. Referring to Table 3 below, the analysis performed with GDMS shows that the titanium carbide raw material is of a purity of at least 99.995%.

TABLE 3
GDMS Analysis (ppm) of titanium raw material and titanium
carbide produced from titanium raw material in embodiment 3

| | iron | nickel | copper | aluminum | sodium | boron | magnesium | vanadium |
|---|---|---|---|---|---|---|---|---|
| Ti | 80 | 5.9 | 150 | 550 | 6.9 | <0.05 | 200 | 0.19 |
| raw material | | | | | | | | |
| TiC | 3.9 | 0.42 | <0.5 | 32 | 0.16 | 0.43 | 0.08 | 0.95 |

In this embodiment, a silicon chip is in a gaseous state when provided at high temperature and low pressure, and porous carbon material reacts at high temperature to produce silicon carbide. In this embodiment, the graphite felt is rather loose and thus decomposes during the reaction in which silicon vapor and the graphite felt react at high temperature to produce silicon carbide and thus synthesize a high-purity silicon carbide powder without comminution, oxidation and acid rinsing. Unlike the prior art, the present invention provides an easy method of producing a carbide raw material, and the raw materials for the carbon source and silicon source for use with the method of producing a carbide raw material are readily available, not to mention that the present invention achieves a 80% conversion rate of the silicon carbide thus synthesized. The production method of the present invention requires less process steps, incurs low costs, and enhances the ease of producing a powder. Furthermore, the production method of the present invention can be applied to synthesizing different metal carbides, including the carbides of titanium, tungsten, boron, zirconium, tantalum, vanadium, aluminum, molybdenum, hafnium, chromium, and neodymium, such that different metal carbides can be easily produced.

Although the present invention is disclosed above by preferred embodiments, the preferred embodiments are not restrictive of the present invention. Any persons skilled in the art can make some changes and modifications to the preferred embodiments without departing from the spirit and scope of the present invention. Accordingly, the legal protection for the present invention should be defined by the appended claims.

What is claimed is:

1. A method of producing a carbide raw material, comprising the steps of:
(A) providing a porous carbon material and a high-purity silicon raw material or a metal raw material and applying the porous carbon material and the high-purity silicon raw material or a metal raw material alternately to form a layer structure;
(B) putting the layer structure in a synthesis furnace to undergo a gas evacuation process; and
(C) producing a carbide raw material with a synthesis reaction which the layer structure undergoes in an inert gas atmosphere, wherein the carbide raw material is a carbide powder of a particle diameter of less than 300 μm.

2. The method of claim 1, wherein the metal raw material is one selected from the group consisting of titanium, tungsten, hafnium, zirconium, vanadium, chromium, tantalum, boron, niobium, aluminum, manganese, nickel, iron, cobalt, molybdenum, and an oxide of the selected one.

3. The method of claim 1, wherein the porous carbon material and the high-purity silicon raw material are of a purity of at least 99.99%.

4. The method of claim 1, wherein the porous carbon material is of a porosity of 20%˜85% and is one selected from the group consisting of a graphite felt, a graphite insulator, a carbon foam, a carbon nanotube, a carbon fiber, and an activated carbon.

5. The method of claim 1, wherein the high-purity silicon raw material silicon is of a thickness of 10 μm˜10000 μm and is one of a silicon wafer, a silicon ingot, a silicon chip, and a silicon briquet.

6. The method of claim 1, wherein the gas evacuation process removes nitrogen gas and oxygen gas from the synthesis furnace, and the synthesis furnace is heated to 900˜1250° C. to remove impurities.

7. The method of claim 1, wherein the synthesis reaction occurs at 1800° C.˜2200° C. and 5˜600 torr.

8. The method of claim 1, wherein step (A) further comprises filling an element raw material at a bottom of the layer structure.

9. The method of claim 8, wherein the element raw material is one of aluminum, boron, vanadium, scandium, iron, cobalt, nickel, and titanium, and a crystal-growing process is performed on the carbide raw material to produce p-type crystals.

10. The method of claim 8, wherein the element raw material is one of nitrogen, phosphorus, arsenic, and stibium, and a crystal-growing process is performed on the carbide raw material to produce n-type crystals.
